(19) United States
(12) Patent Application Publication
(10) Pub. No.: US 2026/0161076 A1
(43) Pub. Date: Jun. 11, 2026

(54) PHOTOSENSITIVE RESIN COMPOSITION, PHOTOSENSITIVE ELEMENT, AND LAMINATE PRODUCTION METHOD

(71) Applicant: Resonac Corporation, Tokyo (JP)

(72) Inventors: Shiho TANAKA, Tokyo (JP); Keishi ONO, Tokyo (JP)

(21) Appl. No.: 18/703,785

(22) PCT Filed: Oct. 24, 2022
(86) PCT No.: PCT/JP2022/039546

§ 371 Date: Apr. 23, 2024

(30) Foreign Application Priority Data
Oct. 26, 2021 (WO) PCT/JP2021/039426

(51) Int. Cl. G03F 7/033; G03F 7/031; H05K 3/46

(52) U.S. Cl. CPC G03F 7/033; G03F 7/031; H05K 3/4644

(57) ABSTRACT

A photosensitive resin composition containing: (A) a binder polymer; (B) a photopolymerizable compound; and (C) a photopolymerization initiator, in which the component (A) includes a binder polymer having a polymerizable monomer having a carboxy group, a styrene compound, an alkyl (meth)acrylate having an alkyl group having 1 to 3 carbon atoms, and an alkyl (meth)acrylate having a linear or branched alkyl group having 4 to 12 carbon atoms as monomer units, the component (B) includes a monofunctional compound having one ethylenically unsaturated bond, and the component (C) includes an acridine compound.

### TECHNICAL FIELD

The present disclosure relates to a photosensitive resin composition, a photosensitive element, a method for producing a laminate, and the like.

### BACKGROUND ART

In the production of laminates that can be used as wiring boards and the like, in a state where resist patterns are formed on a metal layer, an exposed area of the metal layer (a part not covered with the resist patterns) is removed by etching, the resist patterns are then peeled off, and thus desired wirings can be formed. The resist patterns can be formed by exposing and developing a layer of a photosensitive resin composition. As the photosensitive resin composition, various compositions have been investigated. For example, Patent Literature 1 below describes a photosensitive resin composition containing a binder polymer, a photopolymerizable compound, and a specific photopolymerization initiator.

### CITATION LIST

### Patent Literature

Patent Literature 1: Japanese Unexamined Patent Publication No. 2019-028398

### SUMMARY OF INVENTION

### Technical Problem

When a film-shaped photosensitive resin composition is laminated on a base material having a metal layer to form a layer of the photosensitive resin composition, as excellent followability with respect to the base material, for example, it is required to suppress occurrence of voids between the layer of the photosensitive resin composition and the base material.

An object of an aspect of the present disclosure is to provide a photosensitive resin composition having excellent followability with respect to a base material in the case of a film form. An object of another aspect of the present disclosure is to provide a photosensitive element using this photosensitive resin composition. An object of still another aspect of the present disclosure is to provide a method for producing a laminate using the above-described photosensitive resin composition or photosensitive element.

### Solution to Problem

The present disclosure relates to the following [1] to [15] and the like in several aspects.

[1]A photosensitive resin composition containing: (A) a binder polymer; (B) a photopolymerizable compound; and (C) a photopolymerization initiator, in which the component (A) includes a binder polymer having a polymerizable monomer having a carboxy group, a styrene compound, an alkyl (meth)acrylate having an alkyl group having 1 to 3 carbon atoms, and an alkyl (meth)acrylate having a linear or branched alkyl group having 4 to 12 carbon atoms as monomer units, the component (B) includes a monofunctional compound having one ethylenically unsaturated bond, and the component (C) includes an acridine compound.
[2] The photosensitive resin composition described in [1], in which the component (B) includes a nonylphenol EO-modified (meth)acrylate as the monofunctional compound.
[3] The photosensitive resin composition described in [1] or [2], in which a content of the monofunctional compound is 0.1 to 6 parts by mass with respect to a total of 100 parts by mass of the component (A) and the component (B).
[4] The photosensitive resin composition described in any one of [1] to [3], in which the component (B) further includes 2,2-bis(4-((meth)acryloxypolyethoxy)phenyl)propane.
[5] The photosensitive resin composition described in any one of [1] to [3], in which the component (B) further includes 2,2-bis(4-((meth)acryloxypentaethoxy)phenyl)propane.
[6] The photosensitive resin composition described in any one of [1] to [5], in which the component (B) further includes alkylene oxide-modified trimethylolpropane tri(meth)acrylate.
[7] The photosensitive resin composition described in any one of [1] to [6], in which a content of the component (B) is 30 to 60 parts by mass with respect to a total of 100 parts by mass of the component (A) and the component (B).
[8] The photosensitive resin composition described in any one of [1] to [7], in which a content of the monomer unit of the styrene compound is more than 20% by mass on the basis of the total amount of monomer units constituting the component (A).
[9] The photosensitive resin composition described in any one of [1] to [8], in which a weight average molecular weight of the component (A) is 3.0×10⁴ to 5.0×10⁴.
[10] The photosensitive resin composition described in any one of [1] to [9], in which the component (C) further includes a N-phenylglycine compound.
[11] The photosensitive resin composition described in any one of [1] to [10], further containing p-toluenesulfonamide.
[12] The photosensitive resin composition described in any one of [1] to [11], further containing a polymerization inhibitor.
[13] The photosensitive resin composition described in any one of [1] to [12], which is in a film form.
[14]A photosensitive element having: a support; and a photosensitive resin layer disposed on the support, in which the photosensitive resin layer is a layer of the photosensitive resin composition described in any one of [1] to [13].
[15]A method for producing a laminate, the method including: a step of disposing a layer of the photosensitive resin composition on a base material by using the photosensitive resin composition described in any one of [1] to [13] or the photosensitive element described in [14]; a step of photo-curing a part of the layer of the photosensitive resin composition; and a step of removing at least a part of an uncured area of the layer of the photosensitive resin composition to form a cured product pattern.

### Advantageous Effects of Invention

According to an aspect of the present disclosure, it is possible to provide a photosensitive resin composition having excellent followability with respect to a base material in the case of a film form. According to another aspect of the present disclosure, it is possible to provide a photosensitive element using this photosensitive resin composition. According to still another aspect of the present disclosure, it is possible to provide a method for producing a laminate using the above-described photosensitive resin composition or photosensitive element.

### BRIEF DESCRIPTION OF DRAWINGS

FIG. 1 is a schematic cross-sectional view illustrating an example of a photosensitive element.

### DESCRIPTION OF EMBODIMENTS

Hereinafter, embodiments of the present disclosure will be described in detail. However, the present disclosure is not limited to the following embodiments.

In the present specification, a numerical range that has been indicated by use of “to” indicates the range that includes the numerical values which are described before and after “to”, as the minimum value and the maximum value, respectively. The numerical range “A or more” means A and a range of more than A. The numerical range “A or less” means A and a range of less than A. In the numerical ranges that are described stepwise in the present specification, the upper limit value or the lower limit value of the numerical range of a certain stage can be arbitrarily combined with the upper limit value or the lower limit value of the numerical range of another stage. In a numerical range described in the present specification, the upper limit value or the lower limit value of the numerical range may be substituted by a value shown in Examples. “A or B” may include either one of A and B, and may also include both of A and B. Materials listed as examples in the present specification can be used singly or in combinations of two or more kinds, unless otherwise specified. When a plurality of substances corresponding to each component exist in the composition, the content of each component in the composition means the total amount of the plurality of substances that exist in the composition, unless otherwise specified. The term “layer” includes a structure having a shape which is formed on a part, in addition to a structure having a shape which is formed on the whole surface, when the layer has been observed as a plan view. The term “step” includes not only an independent step but also a step by which an intended action of the step is achieved, even though the step cannot be clearly distinguished from other steps. The term “(meth)acrylic acid” means at least one of acrylic acid and methacrylic acid corresponding thereto.

The same applies to other analogous expressions such as “(meth)acrylate”. The content of the (meth)acrylic acid compound means the total amount of the acrylic acid compound and the methacrylic acid compound, and the same applies to other analogous expressions. The “alkyl group” may be linear, branched, or cyclic, unless otherwise specified. The term “EO-modified” means a compound having a polyoxyethylene group. The term “PO-modified” means a compound having a polyoxypropylene group. The term “EO/PO-modified” means a compound having a polyoxyethylene group and a (poly)oxypropylene group.

In the present specification, the solid content of a photosensitive resin composition refers to a non-volatile content of a photosensitive resin composition excluding substances that can volatilize (such as water and an organic solvent). That is, this solid content refers to a component remaining without volatile in drying of the photosensitive resin composition and also includes a component in a liquid, syrupy, waxy state, or the like at room temperature (25° C.).

### <Photosensitive Resin Composition>

A photosensitive resin composition of the present embodiment contains (A) a binder polymer (component (A)), (B) a photopolymerizable compound (component (B)), and (C) a photopolymerization initiator (component (C)). In the photosensitive resin composition of the present embodiment, the component (A) includes a binder polymer having a polymerizable monomer having a carboxy group, a styrene compound, an alkyl (meth)acrylate having an alkyl group having 1 to 3 carbon atoms, and an alkyl (meth)acrylate having a linear or branched alkyl group having 4 to 12 carbon atoms as monomer units, the component (B) includes a monofunctional compound having one ethylenically unsaturated bond, and the component (C) includes an acridine compound.

The photosensitive resin composition of the present embodiment has excellent followability with respect to the base material in the case of being in a film form, and for example, when a film-shaped photosensitive resin composition is laminated on a base material having a metal layer to form a layer of the photosensitive resin composition, it is possible to suppress occurrence of voids between the layer of the photosensitive resin composition and the base material. The photosensitive resin composition of the present embodiment can decrease the diameter of air bubbles, for example, to 115 μm or less (preferably 110 μm or less) in evaluation described in Examples below.

The present inventors have speculated factors for obtaining excellent followability as follows. However, the factors are not limited to the contents to be as follows. That is, it is speculated that the component (A) including a binder polymer having a specific monomer unit can impart flexibility, and excellent followability is obtainable by using such a component (A) in combination with the component (B) and the component (C).

According to one embodiment of the photosensitive resin composition of the present embodiment, excellent sensitivity with respect to an active light ray can be obtained. According to the photosensitive resin composition of the present embodiment, in evaluation described in Examples below, for example, an exposure dose of 30 mJ/cm² or less (preferably, 25 mJ/cm² or less, 23 mJ/cm² or less, and the like) can be obtained.

The photosensitive resin composition of the present embodiment may be in a liquid form and may be in a film form (photosensitive film) as long as this photosensitive resin composition has a property of obtaining excellent followability with respect to a base material in the case of being in a film form. The photosensitive resin composition of the present embodiment has photo-curability and a cured product can be obtained by photo-curing this photosensitive resin composition. A cured product of the present embodiment is a cured product (photo-cured product) of the photosensitive resin composition of the present embodiment. The cured product of the present embodiment may have a patterned shape (cured product pattern), and may be a resist pattern. The shape of a cured product pattern that can be obtained by the photosensitive resin composition of the present embodiment is not particularly limited. The photosensitive resin composition of the present embodiment can be used for forming a resist pattern, the resist pattern may be removed after a treatment using this resist pattern (for example, an etching treatment of a member such as a metal layer disposed under the resist pattern).

The thickness of the layer of the photosensitive resin composition (for example, photosensitive film) or the cured product may be in the following range. The thickness of the layer of the photosensitive resin composition or the cured product may be 100 μm or less, 80 μm or less, 60 μm or less, 50 μm or less, 40 μm or less, 30 μm or less, or 25 μm or less, from the viewpoint of easily obtaining excellent followability. The thickness of the layer of the photosensitive resin composition or the cured product may be 1 μm or more, 3 μm or more, 5 μm or more, 8 μm or more, 10 μm or more, 15 μm or more, 20 μm or more, or 25 μm or more, from the viewpoint of easily obtaining a resist pattern having a sufficient thickness. From these viewpoints, the thickness of the layer of the photosensitive resin composition or the cured product may be 1 to 100 μm. The thickness of the layer of the photosensitive resin composition or the cured product may be an average thickness of ten places thereof.

The photosensitive resin composition of the present embodiment contains a binder polymer as the component (A). The component (A) includes a binder polymer having a polymerizable monomer having a carboxy group (monomer a1), a styrene compound (monomer a2: note that a monomer corresponding to the monomer a1 is excluded), an alkyl (meth)acrylate having an alkyl group having 1 to 3 carbon atoms (monomer a3: note that a monomer corresponding to the monomer a1 or the monomer a2 is excluded), and an alkyl (meth)acrylate having a linear or branched alkyl group having 4 to 12 carbon atoms (monomer a4: note that a monomer corresponding to the monomer a1 or the monomer a2 is excluded) as monomer units. That is, the component (A) includes a binder polymer having a monomer unit A1 of the monomer a1, a monomer unit A2 of the monomer a2, a monomer unit A3 of the monomer a3, and a monomer unit A4 of the monomer a4. The component (A) may not include a binder polymer having a phenolic hydroxyl group.

Examples of the monomer a1 include (meth)acrylic acid, α-bromoacrylic acid, α-chloroacrylic acid, β-furyl (meth)acrylic acid, β-styryl (meth)acrylic acid, maleic acid, maleic anhydride, maleic acid monoesters (such as monomethyl maleate, monoethyl maleate, and monoisopropyl maleate), fumaric acid, cinnamic acid, α-cyanocinnamic acid, itaconic acid, crotonic acid, and propiolic acid. From the viewpoint of easily obtaining excellent followability and the viewpoint of easily improving alkali developability, the monomer a1 may include (meth)acrylic acid and may include methacrylic acid. As the monomer a1, a polymerizable monomer having a carboxy group and an ethylenically unsaturated bond can be used.

The content of the monomer unit A1 may be in the following range on the basis of the total amount of monomer units constituting the component (A). The content of the monomer unit A1 may be 1% by mass or more, 5% by mass or more, 10% by mass or more, 15% by mass or more, 18% by mass or more, 20% by mass or more, or 22% by mass or more, from the viewpoint of easily obtaining excellent followability and the viewpoint of easily improving alkali developability. The content of the monomer unit A1 may be 50% by mass or less, 45% by mass or less, 40% by mass or less, 35% by mass or less, 30% by mass or less, 28% by mass or less, 26% by mass or less, 25% by mass or less, or 22% by mass or less, from the viewpoint of easily obtaining excellent followability. From these viewpoints, the content of the monomer unit A1 may be 1 to 50% by mass, 10 to 40% by mass, or 20 to 30% by mass.

As the monomer a2, at least one selected from the group consisting of styrene and a styrene derivative can be used. Examples of the styrene derivative include a compound in which the hydrogen atom at the α-position or of the aromatic ring of styrene is substituted (such as vinyl toluene and α-methylstyrene).

The content of the monomer unit A2 may be in the following range on the basis of the total amount of monomer units constituting the component (A). The content of the monomer unit A2 may be 1% by mass or more, 5% by mass or more, 10% by mass or more, 15% by mass or more, 18% by mass or more, 20% by mass or more, more than 20% by mass, 22% by mass or more, or 25% by mass or more, from the viewpoint of easily obtaining excellent sensitivity. The content of the monomer unit A2 may be 50% by mass or less, 45% by mass or less, 40% by mass or less, 35% by mass or less, 30% by mass or less, 28% by mass or less, 26% by mass or less, 25% by mass or less, 22% by mass or less, or 20% by mass or less, from the viewpoint of easily obtaining excellent followability. From these viewpoints, the content of the monomer unit A2 may be 1 to 50% by mass, 10 to 40% by mass, or 20 to 30% by mass.

Examples of the monomer a3 include methyl (meth)acrylate, ethyl (meth)acrylate, propyl (meth)acrylate, dimethylaminoethyl (meth)acrylate, diethylaminoethyl (meth)acrylate, glycidyl (meth)acrylate, 2,2,2-trifluoroethyl (meth)acrylate, and 2,2,3,3-tetrafluoropropyl (meth)acrylate. As the monomer a3, an alkyl (meth)acrylate having a substituted or unsubstituted alkyl group having 1 to 3 carbon atoms can be used. The alkyl group in the monomer a3 may be linear or branched.

The content of the monomer unit A3 may be in the following range on the basis of the total amount of monomer units constituting the component (A). The content of the monomer unit A3 may be 10% by mass or more, 15% by mass or more, 20% by mass or more, 25% by mass or more, 30% by mass or more, 35% by mass or more, 40% by mass or more, 45% by mass or more, or 50% by mass or more, from the viewpoint of easily obtaining excellent sensitivity. The content of the monomer unit A3 may be 70% by mass or less, 65% by mass or less, 60% by mass or less, 55% by mass or less, 50% by mass or less, or 45% by mass or less, from the viewpoint of easily obtaining excellent followability. From these viewpoints, the content of the monomer unit A3 may be 10 to 70% by mass, 20 to 60% by mass, or 30 to 50% by mass.

Examples of the monomer a4 include butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate. As the monomer a4, an alkyl (meth)acrylate having a substituted or unsubstituted alkyl group having 4 to 12 carbon atoms can be used. Flexibility is easily imparted by using the monomer a4.

The content of the monomer unit A4 may be in the following range on the basis of the total amount of monomer units constituting the component (A). The content of the monomer unit A4 may be 1% by mass or more, 2% by mass or more, 3% by mass or more, 5% by mass or more, 8% by mass or more, 12% by mass or more, 15% by mass or more, or 17% by mass or more, from the viewpoint of easily obtaining excellent followability. The content of the monomer unit A4 may be 30% by mass or less, 25% by mass or less, 20% by mass or less, 18% by mass or less, 17% by mass or less, 15% by mass or less, 12% by mass or less, 8% by mass or less, 5% by mass or less, or 3% by mass or less, from the viewpoint of easily obtaining excellent sensitivity. From these viewpoints, the content of the monomer unit A4 may be 1 to 30% by mass, 3 to 25% by mass, or 10 to 20% by mass.

The component (A) may have a polymerizable monomer other than the monomers a1 to a4 as a monomer unit. Examples of such a polymerizable monomer include benzyl (meth)acrylate, a benzyl (meth)acrylate derivative, a (meth)acrylamide compound (such as diacetone acrylamide), an ether compound of vinyl alcohol (such as vinyl-n-butyl ether), (meth)acrylonitrile, cycloalkyl (meth)acrylate, furfuryl (meth)acrylate, tetrahydrofurfuryl (meth)acrylate, isobornyl (meth)acrylate, adamantyl (meth)acrylate, dicyclopentenyl (meth)acrylate, dicyclopentenyloxyethyl (meth)acrylate, dicyclopentanyloxyethyl (meth)acrylate, isobornyloxyethyl (meth)acrylate, cyclohexyloxyethyl (meth)acrylate, adamantyloxyethyl (meth)acrylate, dicyclopentenyloxypropyloxyethyl (meth)acrylate, dicyclopentanyloxypropyloxyethyl (meth)acrylate, and adamantyloxypropyloxyethyl (meth)acrylate. As the monomer a4, a polymerizable monomer having an ethylenically unsaturated bond can be used.

A content a1 of a monomer unit not having an aromatic hydrocarbon group and an alicyclic hydrocarbon group may be in the following range on the basis of the total amount of monomer units constituting the component (A). The content a1 may be 50% by mass or more, 60% by mass or more, 65% by mass or more, 70% by mass or more, 75% by mass or more, 78% by mass or more, or 80% by mass or more, from the viewpoint of easily obtaining excellent followability.

The content a1 may be less than 100% by mass, 95% by mass or less, 90% by mass or less, 85% by mass or less, 80% by mass or less, less than 80% by mass, 78% by mass or less, or 75% by mass or less, from the viewpoint of easily obtaining excellent sensitivity. From these viewpoints, the content a1 may be 50% by mass or more and less than 100% by mass, or 50% by mass or more and less than 80% by mass.

The component (A) may include one kind of a binder polymer having the monomers a1 to a4 as monomer units singly or a combination of two or more kinds thereof. The component (A) may include a binder polymer other than the binder polymer having the monomers a1 to a4 as monomer units.

The weight average molecular weight (Mw) of the component (A) may be in the following range. The weight average molecular weight of the component (A) may be 1.0×10⁴ or more, 2.0×10⁴ or more, 2.5×10⁴ or more, 3.0×10⁴ or more, more than 3.0×10⁴, 3.1×10⁴ or more, 3.3×10⁴ or more, 3.5×10⁴ or more, 4.0×10⁴ or more, or 4.5×10⁴ or more, from the viewpoint of easily obtaining excellent sensitivity. The weight average molecular weight of the component (A) may be 10×10⁴ or less, 8.0×10⁴ or less, 7.0×10⁴ or less, less than 7.0×10⁴, 6.5×10⁴ or less, 6.0×10⁴ or less, 5.5×10⁴ or less, 5.0×10⁴ or less, 4.7×10⁴ or less, 4.5×10⁴ or less, 4.0×10⁴ or less, 3.5×10⁴ or less, or 3.0×10⁴ or less, from the viewpoint of easily obtaining excellent followability. From these viewpoints, the weight average molecular weight of the component (A) may be 1.0×10⁴ to 10×10⁴, 2.0×10⁴ to 6.0×10⁴, or 3.0×10⁴ to 5.0×10⁴.

The weight average molecular weight can be measured, for example, by gel permeation chromatography (GPC) using a calibration curve of standard polystyrene. More specifically, it is possible to measure under conditions described in Examples. As for a compound having a low molecular weight, in a case where measurement of the weight average molecular weight is difficult using the above-described method of measuring a weight average molecular weight, it is also possible to measure the molecular weights using other methods and to calculate an average value thereof.

The content of the component (A) may be in the following range on the basis of the total amount (the total amount of solid contents) of the photosensitive resin composition from the viewpoint of easily obtaining excellent followability. The content of the component (A) may be 10% by mass or more, 20% by mass or more, 30% by mass or more, 35% by mass or more, 40% by mass or more, 45% by mass or more, or 50% by mass or more. The content of the component (A) may be 90% by mass or less, 85% by mass or less, 80% by mass or less, 75% by mass or less, 70% by mass or less, 65% by mass or less, 60% by mass or less, or 55% by mass or less. From these viewpoints, the content of the component (A) may be 10 to 90% by mass, 30 to 80% by mass, or 40 to 70% by mass.

The content of the component (A) may be in the following range with respect to a total of 100 parts by mass of the component (A) and the component (B) from the viewpoint of easily obtaining excellent followability. The content of the component (A) may be 10 parts by mass or more, 20 parts by mass or more, 30 parts by mass or more, 35 parts by mass or more, 40 parts by mass or more, 45 parts by mass or more, 50 parts by mass or more, or 54 parts by mass or more. The content of the component (A) may be 90 parts by mass or less, 80 parts by mass or less, 75 parts by mass or less, 70 parts by mass or less, 65 parts by mass or less, 60 parts by mass or less, 55 parts by mass or less, or 54 parts by mass or less. From these viewpoints, the content of the component (A) may be 10 to 90 parts by mass, 30 to 80 parts by mass, or 40 to 70 parts by mass.

In the photosensitive resin composition of the present embodiment, the content of a resin having a phenolic hydroxyl group may be 30% by mass or less, less than 30% by mass, 20% by mass or less, 10% by mass or less, 5% by mass or less, 1% by mass or less, or 0.1% by mass or less, on the basis of the total amount (the total amount of solid contents) of the photosensitive resin composition. The photosensitive resin composition of the present embodiment may not contain a resin having a phenolic hydroxyl group (the above-described content may be substantially 0% by mass).

The photosensitive resin composition of the present embodiment contains a photopolymerizable compound as the component (B). The photopolymerizable compound is a compound that is polymerized by light, and may be a compound having an ethylenically unsaturated bond.

The component (B) includes, as the component (b1), a monofunctional compound having one ethylenically unsaturated bond from the viewpoint of easily obtaining excellent followability.

Examples of the component (b1) include nonylphenol alkylene oxide-modified (meth)acrylate (for example, nonylphenol EO-modified (meth)acrylate (also known as: nonylphenoxypolyethyleneoxy (meth)acrylate)), a phthalic acid-based compound (γ-chloro-β-hydroxypropyl-β′-(meth)acryloyloxyethyl-o-phthalate (also known as: 1-(3-chloro-2-hydroxypropyl)2-[2-((meth)acryloyloxy)ethyl]) phthalate), and alkyl (meth)acrylate. From the viewpoint of easily obtaining excellent followability, as the component (b1), the component (B) may include at least one selected from the group consisting of a nonylphenol alkylene oxide-modified (meth)acrylate and a phthalic acid-based compound, may include a nonylphenol alkylene oxide-modified (meth)acrylate, and may include a nonylphenol EO-modified (meth)acrylate.

As the content of the component (b1), the content of the nonylphenol alkylene oxide-modified (meth)acrylate, or the content of the phthalic acid-based compound, a content b11 may be in the following range on the basis of the total amount of the component (B). The content bit may be 30% by mass or less, 25% by mass or less, 20% by mass or less, 15% by mass or less, 12% by mass or less, 10% by mass or less, 8% by mass or less, 6% by mass or less, or 5% by mass or less, from the viewpoint of easily obtaining excellent followability. The content bit may be more than 0% by mass, 0.01% by mass or more, 0.1% by mass or more, 1% by mass or more, 2% by mass or more, 3% by mass or more, 4% by mass or more, 5% by mass or more, 6% by mass or more, 8% by mass or more, or 10% by mass or more, from the viewpoint of easily obtaining excellent sensitivity. From these viewpoints, the content b11 may be more than 0% by mass and 30% by mass or less, 1 to 20% by mass, or 3 to 12% by mass.

As the content of the component (b1), the content of the nonylphenol alkylene oxide-modified (meth)acrylate, or the content of the phthalic acid-based compound, a content b12 may be in the following range on the basis of the total amount (the total amount of solid contents) of the photosensitive resin composition. The content b12 may be 20% by mass or less, 15% by mass or less, 10% by mass or less, 8% by mass or less, 6% by mass or less, 5% by mass or less, 4% by mass or less, 3% by mass or less, or 2% by mass or less, from the viewpoint of easily obtaining excellent followability. The content b12 may be more than 0% by mass, 0.01% by mass or more, 0.1% by mass or more, 1% by mass or more, 2% by mass or more, 3% by mass or more, or 4% by mass or more, from the viewpoint of easily obtaining excellent sensitivity. From these viewpoints, the content b12 may be more than 0% by mass and 20% by mass or less, 0.1 to 10% by mass, or 1 to 8% by mass.

As the content of the component (b1), the content of the nonylphenol alkylene oxide-modified (meth)acrylate, or the content of the phthalic acid-based compound, a content b13 may be in the following range with respect to a total of 100 parts by mass of the component (A) and the component (B). The content b13 may be 20 parts by mass or less, 15 parts by mass or less, 10 parts by mass or less, 8 parts by mass or less, 6 parts by mass or less, 5 parts by mass or less, 4 parts by mass or less, 3 parts by mass or less, or 2 parts by mass or less, from the viewpoint of easily obtaining excellent followability. The content b13 may be more than 0 parts by mass, 0.01 parts by mass or more, 0.1 parts by mass or more, 1 part by mass or more, 2 parts by mass or more, 3 parts by mass or more, 4 parts by mass or more, or 5 parts by mass or more, from the viewpoint of easily obtaining excellent sensitivity. From these viewpoints, the content b13 may be more than 0 parts by mass and 20 parts by mass or less, 0.1 to 10 parts by mass, 0.1 to 6 parts by mass, or 1 to 6 parts by mass.

From the viewpoint of easily obtaining excellent followability, as the component (b2), the component (B) may include a compound having two ethylenically unsaturated bonds, and may include a (meth)acrylic acid compound having two (meth)acryloyl groups (bifunctional (meth)acrylic acid compound: a compound in which the sum of the acryloyl group and the methacryloyl group is 2).

Examples of the component (b2) include a bisphenol A-type (meth)acrylic acid compound, EO-modified di(meth)acrylate, PO-modified di(meth)acrylate, EO/PO-modified di(meth)acrylate, polyalkylene glycol di(meth)acrylate (such as polyethylene glycol di(meth)acrylate and polypropylene glycol di(meth)acrylate), EO-modified polyalkylene glycol di(meth)acrylate, PO-modified polyalkylene glycol di(meth)acrylate, EO/PO-modified polyalkylene glycol di(meth)acrylate, and trimethylolpropane di(meth)acrylate. The component (B) may include, as the component (b2), a bisphenol A-type (meth)acrylic acid compound from the viewpoint of easily obtaining excellent followability.

From the viewpoint of easily obtaining excellent followability, as the component (b2), the component (B) may include a (meth)acrylic acid compound having a polyoxyalkylene group, and may include a bisphenol A-type (meth)acrylic acid compound having a polyoxyalkylene group. Examples of the bisphenol A-type (meth)acrylic acid compound having a polyoxyalkylene group include 2,2-bis(4-((meth)acryloxypolyethoxy)phenyl)propane, 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropoxy)phenyl)propane.

The component (B) may include 2,2-bis(4-((meth)acryloxypolyethoxy)phenyl)propane in which the number of ethylene oxides added is in the following range, from the viewpoint of easily obtaining excellent followability. The number of ethylene oxides added may be 2 mol or more, 4 mol or more, 6 mol or more, 8 mol or more, or 10 mol or more. The number of ethylene oxides added may be 20 mol or less, 16 mol or less, 12 mol or less, or 10 mol or less. From these viewpoints, the number of ethylene oxides added may be 2 to 20 mol, 2 to 12 mol, 2 to 10 mol, 6 to 20 mol, 6 to 12 mol, or 6 to 10 mol.

From the viewpoint of easily obtaining excellent followability, the component (B) may include 2,2-bis(4-((meth)acryloxypolyethoxy)phenyl)propane, may include at least one selected from the group consisting of 2,2-bis(4-((meth)acryloxypentaethoxy)phenyl)propane and 2,2-bis(4-((meth)acryloxydiethoxy)phenyl)propane, and may include 2,2-bis(4-((meth)acryloxypentaethoxy)phenyl)propane.

The molecular weight of the component (b2) (for example, bisphenol A-type (meth)acrylic acid compound) may be in the following range from the viewpoint of easily obtaining excellent followability. The molecular weight may be 100 or more, 200 or more, 300 or more, 400 or more, 450 or more, 500 or more, 550 or more, 600 or more, 650 or more, 700 or more, 750 or more, or 800 or more. The molecular weight may be 10000 or less, less than 10000, 8000 or less, 6000 or less, 5000 or less, 3000 or less, 2000 or less, 1500 or less, 1000 or less, or 900 or less. From these viewpoints, the molecular weight may be 100 to 10000.

As the content of the component (b2) or the content of the bisphenol A-type (meth)acrylic acid compound, a content b21 may be in the following range on the basis of the total amount of the component (B). The content b21 may be 30% by mass or more, 40% by mass or more, 50% by mass or more, more than 50% by mass, 60% by mass or more, 65% by mass or more, 70% by mass or more, 75% by mass or more, or 80% by mass or more, from the viewpoint of easily obtaining excellent followability. The content b21 is less than 100% by mass, and may be 99% by mass or less, 98% by mass or less, 95% by mass or less, 90% by mass or less, 85% by mass or less, 80% by mass or less, 75% by mass or less, or 70% by mass or less, from the viewpoint of easily obtaining excellent sensitivity. From these viewpoints, the content b21 may be 30% by mass or more and less than 100% by mass, 50 to 99% by mass, or 60 to 90% by mass.

As the content of the component (b2) or the content of the bisphenol A-type (meth)acrylic acid compound, a content b22 may be in the following range on the basis of the total amount (the total amount of solid contents) of the photosensitive resin composition. The content b22 may be 1% by mass or more, 5% by mass or more, 10% by mass or more, 15% by mass or more, 20% by mass or more, 25% by mass or more, 30% by mass or more, 32% by mass or more, or 35% by mass or more, from the viewpoint of easily obtaining excellent followability. The content b22 may be 80% by mass or less, 70% by mass or less, 65% by mass or less, 60% by mass or less, 55% by mass or less, 50% by mass or less, 45% by mass or less, 40% by mass or less, 38% by mass or less, 35% by mass or less, or 32% by mass or less, from the viewpoint of easily obtaining excellent sensitivity. From these viewpoints, the content b22 may be 1 to 80% by mass, 10 to 70% by mass, or 30 to 50% by mass.

As the content of the component (b2) or the content of the bisphenol A-type (meth)acrylic acid compound, a content b23 may be in the following range with respect to a total of 100 parts by mass of the component (A) and the component (B). The content b23 may be 1 part by mass or more, 5 parts by mass or more, 10 parts by mass or more, 15 parts by mass or more, 20 parts by mass or more, 25 parts by mass or more, 30 parts by mass or more, 32 parts by mass or more, 35 parts by mass or more, or 38 parts by mass or more, from the viewpoint of easily obtaining excellent followability. The content b23 may be 80 parts by mass or less, 70 parts by mass or less, 60 parts by mass or less, 50 parts by mass or less, 45 parts by mass or less, 40 parts by mass or less, 38 parts by mass or less, 35 parts by mass or less, or 32 parts by mass or less, from the viewpoint of easily obtaining excellent sensitivity. From these viewpoints, the content b23 may be 1 to 80 parts by mass, 10 to 70 parts by mass, or 20 to 50 parts by mass.

From the viewpoint of easily obtaining excellent followability, as a component (b3), the component (B) may include a compound having three or more ethylenically unsaturated bonds, and may include a (meth)acrylic acid compound having three or more (meth)acryloyl groups (tri- or higher functional (meth)acrylic acid compound: a compound in which the sum of the acryloyl group and the methacryloyl group is 3 or more).

The component (B) may include, as the component (b3), a compound in which the number of ethylenically unsaturated bonds is in the following range. The number of ethylenically unsaturated bonds in the component (b3) is 3 or more, and may be 4 or more, 5 or more, or 6 or more from the viewpoint of easily obtaining excellent sensitivity. The number of ethylenically unsaturated bonds in the component (b3) may be 10 or less, 8 or less, 6 or less, 5 or less, or 4 or less from the viewpoint of easily obtaining excellent followability. From these viewpoints, the number of ethylenically unsaturated bonds in the component (b3) may be 3 to 10.

From the viewpoint of easily obtaining excellent followability, as the component (b3), the component (B) may include a compound having three ethylenically unsaturated bonds, and may include a compound having six ethylenically unsaturated bonds. The component (B) may include two or more kinds of the component (b3), and may include a compound having three ethylenically unsaturated bonds and a compound having six ethylenically unsaturated bonds from the viewpoint of easily obtaining excellent followability.

The component (B) may include, as the component (b3), a (meth)acrylic acid compound in which the number of (meth)acryloyl groups (the sum of the acryloyl group and the methacryloyl group) is in the following range. The number of (meth)acryloyl groups in the component (b3) may be 3 or more, 4 or more, 5 or more, or 6 or more from the viewpoint of easily obtaining excellent sensitivity. The number of (meth)acryloyl groups in the component (b3) may be 10 or less, 8 or less, 6 or less, 5 or less, or 4 or less from the viewpoint of easily obtaining excellent followability. From these viewpoints, the number of (meth)acryloyl groups in the component (b3) may be 3 to 10.

Examples of the component (b3) include trimethylolpropane tri(meth)acrylate; alkylene oxide-modified trimethylolpropane tri(meth)acrylates such as EO-modified trimethylolpropane tri(meth)acrylate, PO-modified trimethylolpropane tri(meth)acrylate, and EO/PO-modified trimethylolpropane tri(meth)acrylate; tetramethylolmethane tri(meth)acrylate; tetramethylolmethane tetra(meth)acrylate; pentaerythritol tetra(meth)acrylate; alkylene oxide-modified pentaerythritol tetra(meth)acrylates such as EO-modified pentaerythritol tetra(meth)acrylate, PO-modified pentaerythritol tetra(meth)acrylate, and EO/PO-modified pentaerythritol tetra(meth)acrylate; dipentaerythritol hexa(meth)acrylate; and alkylene oxide-modified dipentaerythritol hexa(meth)acrylates such as EO-modified dipentaerythritol hexa(meth)acrylate, PO-modified dipentaerythritol hexa(meth)acrylate, and EO/PO-modified dipentaerythritol hexa(meth)acrylate. From the viewpoint of easily obtaining excellent followability, as the component (b3), the component (B) may include at least one selected from the group consisting of trimethylolpropane tri(meth)acrylate, alkylene oxide-modified trimethylolpropane tri(meth)acrylate, dipentaerythritol hexa(meth)acrylate, and alkylene oxide-modified dipentaerythritol hexa(meth)acrylate, and may include alkylene oxide-modified trimethylolpropane tri(meth)acrylate.

From the viewpoint of easily obtaining excellent followability, as the component (b3), the component (B) may include a (meth)acrylic acid compound having a polyoxyalkylene group, may include at least one selected from the group consisting of alkylene oxide-modified trimethylolpropane tri(meth)acrylate and alkylene oxide-modified dipentaerythritol hexa(meth)acrylate, and may include at least one selected from the group consisting of EO-modified trimethylolpropane tri(meth)acrylate, PO-modified trimethylolpropane tri(meth)acrylate, EO/PO-modified trimethylolpropane tri(meth)acrylate, EO-modified dipentaerythritol hexa(meth)acrylate, PO-modified dipentaerythritol hexa(meth)acrylate, and EO/PO-modified dipentaerythritol hexa(meth)acrylate.

The molecular weight of the component (b3) may be in the following range. The molecular weight may be 100 or more, 200 or more, 300 or more, 400 or more, 500 or more, 600 or more, 700 or more, 750 or more, 800 or more, 900 or more, 1000 or more, 1100 or more, or 1200 or more, from the viewpoint of easily obtaining excellent followability. The molecular weight may be 10000 or less, less than 10000, 8000 or less, 6000 or less, 5000 or less, 3000 or less, 2000 or less, 1500 or less, 1300 or less, or 1200 or less, from the viewpoint of easily obtaining excellent sensitivity. From these viewpoints, the molecular weight may be 100 to 10000.

The content of the component (b3) may be in the following range on the basis of the total amount of the component (B). The content of the component (b3) may be more than 0% by mass, 1% by mass or more, 3% by mass or more, 5% by mass or more, 8% by mass or more, 10% by mass or more, 12% by mass or more, 13% by mass or more, 15% by mass or more, or 18% by mass or more, from the viewpoint of easily obtaining excellent sensitivity. The content of the component (b3) may be 50% by mass or less, less than 50% by mass, 40% by mass or less, 30% by mass or less, 25% by mass or less, 20% by mass or less, 18% by mass or less, or 15% by mass or less, from the viewpoint of easily obtaining excellent followability. From these viewpoints, the content of the component (b3) may be more than 0% by mass and 50% by mass or less, 5 to 40% by mass, or 10 to 30% by mass.

The content of the alkylene oxide-modified trimethylolpropane tri(meth)acrylate may be in the following range on the basis of the total amount of the component (B). The content of the alkylene oxide-modified trimethylolpropane tri(meth)acrylate may be more than 0% by mass, 1% by mass or more, 3% by mass or more, 5% by mass or more, 8% by mass or more, 10% by mass or more, 12% by mass or more, or 13% by mass or more, from the viewpoint of easily obtaining excellent followability. The content of the alkylene oxide-modified trimethylolpropane tri(meth)acrylate may be 50% by mass or less, less than 50% by mass, 40% by mass or less, 30% by mass or less, 25% by mass or less, 20% by mass or less, 18% by mass or less, 15% by mass or less, 13% by mass or less, 12% by mass or less, or 10% by mass or less, from the viewpoint of easily obtaining excellent sensitivity. From these viewpoints, the content of the alkylene oxide-modified trimethylolpropane tri(meth)acrylate may be more than 0% by mass and 50% by mass or less, 1 to 40% by mass, or 5 to 30% by mass.

The content of the alkylene oxide-modified dipentaerythritol hexa(meth)acrylate may be in the following range on the basis of the total amount of the component (B) from the viewpoint of easily obtaining excellent sensitivity. The content of the alkylene oxide-modified dipentaerythritol hexa(meth)acrylate may be more than 0% by mass, 1% by mass or more, 3% by mass or more, 5% by mass or more, 8% by mass or more, or 10% by mass or more. The content of the alkylene oxide-modified dipentaerythritol hexa(meth)acrylate may be 50% by mass or less, less than 50% by mass, 40% by mass or less, 30% by mass or less, 25% by mass or less, 20% by mass or less, 18% by mass or less, 15% by mass or less, 13% by mass or less, or 12% by mass or less. From these viewpoints, the content of the alkylene oxide-modified dipentaerythritol hexa(meth)acrylate may be more than 0% by mass and 50% by mass or less, 1 to 40% by mass, or 5 to 30% by mass.

The content of the component (b3) may be in the following range on the basis of the total amount (the total amount of solid contents) of the photosensitive resin composition. The content of the component (b3) may be more than 0% by mass, 0.1% by mass or more, 1% by mass or more, 2% by mass or more, 3% by mass or more, 4% by mass or more, 5% by mass or more, 6% by mass or more, 7% by mass or more, or 8% by mass or more, from the viewpoint of easily obtaining excellent sensitivity. The content of the component (b3) may be 30% by mass or less, 25% by mass or less, 20% by mass or less, 15% by mass or less, 13% by mass or less, 12% by mass or less, 10% by mass or less, 9% by mass or less, 8% by mass or less, 7% by mass or less, or 6% by mass or less, from the viewpoint of easily obtaining excellent followability. From these viewpoints, the content of the component (b3) may be more than 0% by mass and 30% by mass or less, 0.1 to 20% by mass, or 1 to 10% by mass.

The content of the alkylene oxide-modified trimethylolpropane tri(meth)acrylate may be in the following range on the basis of the total amount (the total amount of solid contents) of the photosensitive resin composition. The content of the alkylene oxide-modified trimethylolpropane tri(meth)acrylate may be more than 0% by mass, 0.1% by mass or more, 1% by mass or more, 2% by mass or more, 3% by mass or more, 4% by mass or more, or 5% by mass or more, from the viewpoint of easily obtaining excellent followability. The content of the alkylene oxide-modified trimethylolpropane tri(meth)acrylate may be 30% by mass or less, 25% by mass or less, 20% by mass or less, 15% by mass or less, 13% by mass or less, 12% by mass or less, 10% by mass or less, 9% by mass or less, 8% by mass or less, 7% by mass or less, 6% by mass or less, 5% by mass or less, or 4% by mass or less, from the viewpoint of easily obtaining excellent sensitivity. From these viewpoints, the content of the alkylene oxide-modified trimethylolpropane tri(meth)acrylate may be more than 0% by mass and 30% by mass or less, 0.1 to 20% by mass, or 1 to 10% by mass.

The content of the alkylene oxide-modified dipentaerythritol hexa(meth)acrylate may be in the following range on the basis of the total amount (the total amount of solid contents) of the photosensitive resin composition from the viewpoint of easily obtaining excellent sensitivity. The content of the alkylene oxide-modified dipentaerythritol hexa(meth)acrylate may be more than 0% by mass, 0.1% by mass or more, 1% by mass or more, 2% by mass or more, 3% by mass or more, or 4% by mass or more. The content of the alkylene oxide-modified dipentaerythritol hexa(meth)acrylate may be 30% by mass or less, 25% by mass or less, 20% by mass or less, 15% by mass or less, 13% by mass or less, 12% by mass or less, 10% by mass or less, 9% by mass or less, 8% by mass or less, 7% by mass or less, 6% by mass or less, or 5% by mass or less. From these viewpoints, the content of the alkylene oxide-modified dipentaerythritol hexa(meth)acrylate may be more than 0% by mass and 30% by mass or less, 0.1 to 20% by mass, or 1 to 10% by mass.

The content of the component (b3) may be in the following range with respect to a total of 100 parts by mass of the component (A) and the component (B). The content of the component (b3) may be more than 0 parts by mass, 1 part by mass or more, 2 parts by mass or more, 3 parts by mass or more, 4 parts by mass or more, 5 parts by mass or more, 6 parts by mass or more, 7 parts by mass or more, 8 parts by mass or more, or 9 parts by mass or more, from the viewpoint of easily obtaining excellent sensitivity. The content of the component (b3) may be 30 parts by mass or less, 25 parts by mass or less, 20 parts by mass or less, 15 parts by mass or less, 14 parts by mass or less, 12 parts by mass or less, 10 parts by mass or less, 9 parts by mass or less, 8 parts by mass or less, 7 parts by mass or less, or 6 parts by mass or less, from the viewpoint of easily obtaining excellent followability. From these viewpoints, the content of the component (b3) may be more than 0 parts by mass and 30 parts by mass or less, 0.1 to 20 parts by mass, or 1 to 10 parts by mass.

The content of the alkylene oxide-modified trimethylolpropane tri(meth)acrylate may be in the following range with respect to a total of 100 parts by mass of the component (A) and the component (B). The content of the alkylene oxide-modified trimethylolpropane tri(meth)acrylate may be more than 0 parts by mass, 1 part by mass or more, 2 parts by mass or more, 3 parts by mass or more, 4 parts by mass or more, 5 parts by mass or more, or 6 parts by mass or more, from the viewpoint of easily obtaining excellent followability. The content of the alkylene oxide-modified trimethylolpropane tri(meth)acrylate may be 30 parts by mass or less, 25 parts by mass or less, 20 parts by mass or less, 15 parts by mass or less, 14 parts by mass or less, 12 parts by mass or less, 10 parts by mass or less, 9 parts by mass or less, 8 parts by mass or less, 7 parts by mass or less, 6 parts by mass or less, 5 parts by mass or less, or 4 parts by mass or less, from the viewpoint of easily obtaining excellent sensitivity. From these viewpoints, the content of the alkylene oxide-modified trimethylolpropane tri(meth)acrylate may be more than 0 parts by mass and 30 parts by mass or less, 0.1 to 20 parts by mass, or 1 to 10 parts by mass.

The content of the alkylene oxide-modified dipentaerythritol hexa(meth)acrylate may be in the following range with respect to a total of 100 parts by mass of the component (A) and the component (B) from the viewpoint of easily obtaining excellent sensitivity. The content of the alkylene oxide-modified dipentaerythritol hexa(meth)acrylate may be more than 0 parts by mass, 1 part by mass or more, 2 parts by mass or more, 3 parts by mass or more, 4 parts by mass or more, or 5 parts by mass or more. The content of the alkylene oxide-modified dipentaerythritol hexa(meth)acrylate may be 30 parts by mass or less, 25 parts by mass or less, 20 parts by mass or less, 15 parts by mass or less, 14 parts by mass or less, 12 parts by mass or less, 10 parts by mass or less, 9 parts by mass or less, 8 parts by mass or less, 7 parts by mass or less, 6 parts by mass or less, or 5 parts by mass or less. From these viewpoints, the content of the alkylene oxide-modified dipentaerythritol hexa(meth)acrylate may be more than 0 parts by mass and 30 parts by mass or less, 0.1 to 20 parts by mass, or 1 to 10 parts by mass.

The content of the component (B) may be in the following range on the basis of the total amount (the total amount of solid contents) of the photosensitive resin composition from the viewpoint of easily obtaining excellent followability. The content of the component (B) may be 10% by mass or more, 15% by mass or more, 20% by mass or more, 25% by mass or more, 30% by mass or more, 35% by mass or more, 40% by mass or more, or 43% by mass or more. The content of the component (B) may be 90% by mass or less, 80% by mass or less, 70% by mass or less, 65% by mass or less, 60% by mass or less, 55% by mass or less, 50% by mass or less, or 45% by mass or less. From these viewpoints, the content of the component (B) may be 10 to 90% by mass, 20 to 70% by mass, or 30 to 60% by mass.

The content of the component (B) may be in the following range with respect to a total of 100 parts by mass of the component (A) and the component (B) from the viewpoint of easily obtaining excellent followability. The content of the component (B) may be 10 parts by mass or more, 20 parts by mass or more, 25 parts by mass or more, 30 parts by mass or more, 35 parts by mass or more, 40 parts by mass or more, 45 parts by mass or more, or 46 parts by mass or more. The content of the component (B) may be 90 parts by mass or less, 80 parts by mass or less, 70 parts by mass or less, 65 parts by mass or less, 60 parts by mass or less, 55 parts by mass or less, 50 parts by mass or less, or 46 parts by mass or less. From these viewpoints, the content of the component (B) may be 10 to 90 parts by mass, 20 to 70 parts by mass, or 30 to 60 parts by mass.

In the photosensitive resin composition of the present embodiment, the content of a (meth)acrylic acid compound having an isocyanuric ring structure or the content of a photopolymerizable compound having an ethylenically unsaturated group and an isocyanuric ring structure may be 1 part by mass or less, less than 1 part by mass, 0.1 parts by mass or less, 0.01 parts by mass or less, or 0.001 parts by mass or less with respect to a total of 100 parts by mass of the component (A) and the component (B). The photosensitive resin composition of the present embodiment may not contain a (meth)acrylic acid compound having an isocyanuric ring structure (the above-described content may be substantially 0 parts by mass), and may not contain a photopolymerizable compound having an ethylenically unsaturated group and an isocyanuric ring structure (the above-described content may be substantially 0 parts by mass).

In the photosensitive resin composition of the present embodiment, the content of at least one selected from the group consisting of a photopolymerizable compound having a skeleton derived from pentaerythritol and a photopolymerizable compound having a skeleton derived from dipentaerythritol may be 3 parts by mass or less, less than 3 parts by mass, 1 part by mass or less, 0.1 parts by mass or less, or 0.01 parts by mass or less, with respect to a total of 100 parts by mass of the component (A) and the component (B). The photosensitive resin composition of the present embodiment may not contain at least one selected from the group consisting of a photopolymerizable compound having a skeleton derived from pentaerythritol and a photopolymerizable compound having a skeleton derived from dipentaerythritol (the content thereof may be substantially 0 parts by mass with respect to a total of 100 parts by mass of the component (A) and the component (B)). In the photosensitive resin composition of the present embodiment, the content of at least one selected from the group consisting of a (meth)acrylic acid compound having a skeleton derived from pentaerythritol and a (meth)acrylic acid compound having a skeleton derived from dipentaerythritol may be 3 parts by mass or less, less than 3 parts by mass, 1 part by mass or less, 0.1 parts by mass or less, or 0.01 parts by mass or less, with respect to a total of 100 parts by mass of the component (A) and the component (B). The photosensitive resin composition of the present embodiment may not contain at least one selected from the group consisting of a (meth)acrylic acid compound having a skeleton derived from pentaerythritol and a (meth)acrylic acid compound having a skeleton derived from dipentaerythritol (the content thereof may be substantially 0 parts by mass with respect to a total of 100 parts by mass of the component (A) and the component (B)).

In the photosensitive resin composition of the present embodiment, the content of a bisphenol F-type (meth)acrylic acid compound may be 5% by mass or less, less than 5% by mass, 1% by mass or less, less than 1% by mass, 0.1% by mass or less, or substantially 0% by mass, on the basis of the total amount of the component (B). In the photosensitive resin composition of the present embodiment, the content of a bisphenol F-type (meth)acrylic acid compound may be 0.2% by mass or less, 0.15% by mass or less, less than 0.15% by mass, 0.1% by mass or less, or 0.01% by mass or less, on the basis of the total amount (the total amount of solid contents) of the photosensitive resin composition. The photosensitive resin composition of the present embodiment may not contain a bisphenol F-type (meth)acrylic acid compound (the above-described content may be substantially 0% by mass).

In the photosensitive resin composition of the present embodiment, the content of an epoxy compound having two or more oxirane rings may be 20 parts by mass or less, less than 20 parts by mass, 10 parts by mass or less, less than 10 parts by mass, 1 part by mass or less, or substantially 0 parts by mass, with respect to 100 parts by mass of the component (A). The photosensitive resin composition of the present embodiment may not contain an epoxy compound having two or more oxirane rings (the content of the epoxy compound having two or more oxirane rings may be substantially 0% by mass on the basis of the total amount (the total amount of solid contents) of the photosensitive resin composition).

The photosensitive resin composition of the present embodiment contains a photopolymerization initiator as the component (C). The component (C) includes an acridine compound from the viewpoint of easily obtaining excellent followability. Examples of the acridine compound include 9-phenylacridine and 1,7-bis(9,9′-acridine)heptane.

The component (C) may include a photopolymerization initiator other than the acridine compound. Examples of such a photopolymerization initiator include N-phenylglycine compounds such as N-phenylglycine and a N-phenylglycine derivative; a hexaarylbiimidazole compound; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl)ketone, and 2-methyl-1-[4-(methylthio)phenyl]-2-morpholino-propanone-1; quinone compounds such as alkylanthraquinone; benzoinether compounds such as benzoinalkyl ethers; benzoin compounds such as benzoin and alkylbenzoin; benzyl derivatives such as benzyldimethylketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer. The hexaarylbiimidazole compound may include a 2-(o-chlorophenyl)-4,5-diphenylimidazole dimer, and may include 2,2′-bis(o-chlorophenyl)-4,4′,5,5′-tetraphenyl-1,2′-biimidazole.

The component (C) may include a N-phenylglycine compound in addition to the acridine compound from the viewpoint of easily obtaining excellent followability. The total amount of the acridine compound and the N-phenylglycine compound may be 50% by mass or more, more than 50% by mass, 70% by mass or more, 90% by mass or more, 95% by mass or more, 98% by mass or more, 99% by mass or more, or substantially 100% by mass (an embodiment in which the component (C) is substantially composed of the acridine compound and the N-phenylglycine compound), on the basis of the total amount of the component (C), from the viewpoint of easily obtaining excellent followability.

The content of the acridine compound may be in the following range on the basis of the total amount of the component (C) from the viewpoint of easily obtaining excellent followability. The content of the acridine compound may be 50% by mass or more, more than 50% by mass, 70% by mass or more, 80% by mass or more, 90% by mass or more, 95% by mass or more, 96% by mass or more, or 97% by mass or more. The content of the acridine compound may be 100% by mass or less, less than 100% by mass, 99% by mass or less, or 98% by mass or less. From these viewpoints, the content of the acridine compound may be 50 to 100% by mass.

The content of the N-phenylglycine compound may be in the following range on the basis of the total amount of the component (C) from the viewpoint of easily obtaining excellent followability. The content of the N-phenylglycine compound may be more than 0% by mass, 1% by mass or more, or 2% by mass or more. The content of the N-phenylglycine compound may be 50% by mass or less, less than 50% by mass, 30% by mass or less, 20% by mass or less, 10% by mass or less, 5% by mass or less, 4% by mass or less, or 3% by mass or less. From these viewpoints, the content of the N-phenylglycine compound may be more than 0% by mass and 50% by mass or less.

As the content of the component (C) or the content of the acridine compound, a content c1 may be in the following range on the basis of the total amount (the total amount of solid contents) of the photosensitive resin composition from the viewpoint of easily obtaining excellent followability. The content c1 may be more than 0% by mass, 0.1% by mass or more, 0.3% by mass or more, 0.5% by mass or more, 0.8% by mass or more, 0.9% by mass or more, 1% by mass or more, or 1.1% by mass or more. The content c1 may be 10% by mass or less, 50% by mass or less, 4% by mass or less, 3% by mass or less, 2.5% by mass or less, 2% by mass or less, 1.5% by mass or less, or 1.2% by mass or less. From these viewpoints, the content c1 may be more than 0% by mass and 10% by mass or less.

The content of the N-phenylglycine compound may be in the following range on the basis of the total amount (the total amount of solid contents) of the photosensitive resin composition from the viewpoint of easily obtaining excellent followability. The content of the N-phenylglycine compound may be more than 0% by mass, 0.001% by mass or more, 0.005% by mass or more, 0.01% by mass or more, 0.015% by mass or more, 0.02% by mass or more, or 0.025% by mass or more. The content of the N-phenylglycine compound may be 1% by mass or less, 0.5% by mass or less, 0.1% by mass or less, 0.08% by mass or less, 0.05% by mass or less, 0.04% by mass or less, or 0.03% by mass or less. From these viewpoints, the content of the N-phenylglycine compound may be more than 0% by mass and 1% by mass or less.

As the content of the component (C) or the content of the acridine compound, a content c2 may be in the following range with respect to a total of 100 parts by mass of the component (A) and the component (B) from the viewpoint of easily obtaining excellent followability. The content c2 may be more than 0 parts by mass, 0.1 parts by mass or more, 0.3 parts by mass or more, 0.5 parts by mass or more, 0.8 parts by mass or more, 0.9 parts by mass or more, 1 part by mass or more, 1.1 parts by mass or more, or 1.2 parts by mass or more. The content c2 may be 10 parts by mass or less, 5 parts by mass or less, 4 parts by mass or less, 3.5 parts by mass or less, 3 parts by mass or less, 2.5 parts by mass or less, 2 parts by mass or less, 1.5 parts by mass or less, 1.3 parts by mass or less, or 1.2 parts by mass or less. From these viewpoints, the content c2 may be more than 0 parts by mass and 10 parts by mass or less.

The content of the N-phenylglycine compound may be in the following range with respect to a total of 100 parts by mass of the component (A) and the component (B) from the viewpoint of easily obtaining excellent followability. The content of the N-phenylglycine compound may be more than 0 parts by mass, 0.001 parts by mass or more, 0.005 parts by mass or more, 0.01 parts by mass or more, 0.015 parts by mass or more, 0.02 parts by mass or more, 0.025 parts by mass or more, or 0.03 parts by mass or more. The content of the N-phenylglycine compound may be 1 part by mass or less, 0.5 parts by mass or less, 0.1 parts by mass or less, 0.08 parts by mass or less, 0.05 parts by mass or less, 0.04 parts by mass or less, or 0.03 parts by mass or less. From these viewpoints, the content of the N-phenylglycine compound may be more than 0 parts by mass and 10 parts by mass or less.

The photosensitive resin composition of the present embodiment may contain a polymerization inhibitor (excluding a compound corresponding to any one of the components (A) to (C)). Examples of the polymerization inhibitor include a catechol compound (for example, tert-butylcatechol such as 4-tert-butylcatechol), hindered amine (for example, 2,2,6,6-tetramethyl-4-hydroxypiperidine-1-oxyl), and 4-hydroxy-2,2,6,6-tetramethylpiperidine-N-oxyl.

The photosensitive resin composition of the present embodiment may contain an organic solvent (excluding a compound corresponding to any one of the components (A) to (C)). Examples of the organic solvent include methanol, ethanol, acetone, methyl ethyl ketone, methyl cellosolve, ethyl cellosolve, toluene, N,N-dimethylformamide, and propylene glycol monomethyl ether.

The photosensitive resin composition of the present embodiment may contain other component (excluding a compound corresponding to any one of the components (A) to (C)). Examples of other component include hydrogen donors (such as bis[4-(dimethylamino)phenyl]methane, bis[4-(diethylamino)phenyl]methane, and leuco crystal violet, N-phenylglycine), dyes (such as malachite green), tribromophenylsulfone, tribromomethyl phenyl sulfone, a vinyl polymer, an oxetane compound, an anthracene compound (such as 9,10-dibutoxyanthracene), a distyrylbenzene compound, a naphthalene compound, a nitroxyl compound, a mercapto compound (a compound having a mercapto group; such as 2-mercaptobenzimidazole), sensitizers, photochromic agents, thermochromic inhibitors, plasticizers (such as p-toluenesulfonamide), pigments, fillers, antifoaming agents, flame retardants, stabilizers, tackifiers, leveling agents, release promoters, antioxidants, aromatics, imaging agents, thermal crosslinking agents, and thermal radical polymerization initiators. From the viewpoint of easily obtaining excellent followability, the photosensitive resin composition of the present embodiment may contain tribromomethyl phenyl sulfone. From the viewpoint of easily obtaining excellent followability, the photosensitive resin composition of the present embodiment may contain p-toluenesulfonamide.

In the photosensitive resin composition of the present embodiment, the content of the thermal radical polymerization initiator may be 0.5% by mass or less, less than 0.5% by mass, 0.1% by mass or less, 0.01% by mass or less, or 0.001% by mass or less, on the basis of the total amount (the total amount of solid contents) of the photosensitive resin composition. The photosensitive resin composition of the present embodiment may not contain a thermal radical polymerization initiator (the above-described content may be substantially 0% by mass).

In the photosensitive resin composition of the present embodiment, the content of at least one selected from the group consisting of a vinyl polymer (for example, a vinyl polymer having a side chain having an epoxy group) and an oxetane compound (for example, an oxetane compound having two or more oxetane rings which may have a substituent) may be 20% by mass or less, less than 20% by mass, 10% by mass or less, 1% by mass or less, 0.1% by mass or less, 0.01% by mass or less, or 0.001% by mass or less, on the basis of the total amount (the total amount of solid contents) of the photosensitive resin composition. The photosensitive resin composition of the present embodiment may not contain at least one selected from the group consisting of a vinyl polymer (for example, a vinyl polymer having a side chain having an epoxy group) and an oxetane compound (for example, an oxetane compound having two or more oxetane rings which may have a substituent) (the above-described content may be substantially 0% by mass).

In the photosensitive resin composition of the present embodiment, the content of at least one selected from the group consisting of an anthracene compound, a distyrylbenzene compound, and a naphthalene compound may be 0.01% by mass or less, less than 0.01% by mass, 0.001% by mass or less, or 0.0001% by mass or less, on the basis of the total amount (the total amount of solid contents) of the photosensitive resin composition. The photosensitive resin composition of the present embodiment may not contain at least one selected from the group consisting of an anthracene compound, a distyrylbenzene compound, and a naphthalene compound (the above-described content may be substantially 0% by mass).

In the photosensitive resin composition of the present embodiment, the content of the nitroxyl compound may be 0.005 parts by mass or less, less than 0.005 parts by mass, 0.001 parts by mass or less, or 0.0001 parts by mass or less with respect to 100 parts by mass of the component (A) or a total of 100 parts by mass of the component (A) and the component (B). The photosensitive resin composition of the present embodiment may not contain a nitroxyl compound (the above-described content may be substantially 0 parts by mass).

In the photosensitive resin composition of the present embodiment, the content of the mercapto compound may be 0.1 parts by mass or less, less than 0.1 parts by mass, 0.001 parts by mass or less, less than 0.001 parts by mass, or 0.0001 parts by mass or less with respect to a total of 100 parts by mass of the component (A) and the component (B). The photosensitive resin composition of the present embodiment may not contain a mercapto compound (the above-described content may be substantially 0 parts by mass).

In the photosensitive resin composition of the present embodiment, the content of an acid-modified vinyl group-containing epoxy resin may be 20% by mass or less, less than 20% by mass, 10% by mass or less, 1% by mass or less, 0.1% by mass or less, or 0.01% by mass or less, on the basis of the total amount (the total amount of solid contents) of the photosensitive resin composition. The photosensitive resin composition of the present embodiment may not contain an acid-modified vinyl group-containing epoxy resin (the above-described content may be substantially 0% by mass). The acid-modified vinyl group-containing epoxy resin can be obtained by modifying the epoxy resin with an acid having a vinyl group.

In the photosensitive resin composition of the present embodiment, the content of an acyl phosphine oxide-based photopolymerization initiator may be 0.2% by mass or less, less than 0.2% by mass, 0.1% by mass or less, 0.01% by mass or less, or 0.001% by mass or less, on the basis of the total amount (the total amount of solid contents) of the photosensitive resin composition. The photosensitive resin composition of the present embodiment may not contain an acyl phosphine oxide-based photopolymerization initiator (the above-described content may be substantially 0% by mass).

### <Photosensitive Element>

A photosensitive element of the present embodiment includes a support and a photosensitive resin layer disposed on the support, and the photosensitive resin layer is a layer of the photosensitive resin composition of the present embodiment. The photosensitive element of the present embodiment may include a protective layer disposed on the photosensitive resin layer. The photosensitive element of the present embodiment may include a cushion layer, an adhesive layer, a light-absorbing layer, a gas barrier layer, or the like. The photosensitive element may be in a sheet form, or may be in the form of a photosensitive element roll being wound around a core into a roll.

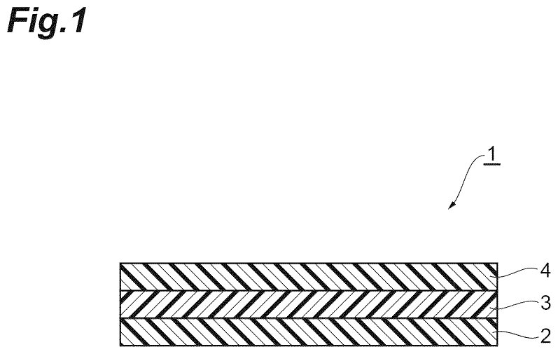

FIG. 1 is a schematic cross-sectional view illustrating an example of a photosensitive element. As illustrated in FIG. 1, a photosensitive element 1 includes a support (support film) 2, a photosensitive resin layer 3 disposed on the support 2, and a protective layer (protective film) 4 disposed on the photosensitive resin layer 3. The photosensitive resin layer 3 is composed of the photosensitive resin composition of the present embodiment.

The photosensitive element 1 can be obtained, for example, by the following procedure. First, the photosensitive resin layer 3 is formed on the support 2. The photosensitive resin layer 3 can be formed, for example, by drying a coating layer formed by applying a photosensitive resin composition containing an organic solvent. Next, the protective layer 4 is disposed on the photosensitive resin layer 3.

Each of the support and the protective layer may be a polymer film having heat resistance and solvent resistance, and may be a polyester film (such as a polyethylene terephthalate film), a polyolefin film (such as a polyethylene film or a polypropylene film), a hydrocarbon-based polymer (excluding a polyolefin film), or the like. The type of the film constituting the protective layer and the type of the film constituting the support may be the same as or different from each other.

The thickness of the support may be 1 μm or more, 5 μm or more, 10 μm or more, or 15 μm or more, from the viewpoint of easily suppressing the damage of the support when the support is peeled off from the photosensitive resin layer. The thickness of the support may be 100 μm or less, 50 μm or less, 30 μm or less, or 20 μm or less, from the viewpoint of suitably performing exposure in the case of exposure through the support.

The thickness of the protective layer may be 1 μm or more, 5 μm or more, 10 μm or more, or 15 μm or more, from the viewpoint of easily suppressing the damage of the protective layer when the photosensitive resin layer and the support are laminated on the base material while the protective layer is peeled off. The thickness of the protective layer may be 100 μm or less, 50 μm or less, or 30 μm or less, from the viewpoint of easily improving productivity.

### <Method for Producing Laminate>

A method for producing a laminate of the present embodiment includes a disposing step (photosensitive resin layer disposing step) of disposing a photosensitive resin layer (a layer of the photosensitive resin composition) on a base material by using the photosensitive resin composition of the present embodiment or the photosensitive element of the present embodiment, an exposure step of photo-curing (exposing) a part of the photosensitive resin layer, and a development step of removing at least a part of an uncured area (unexposed area) of the photosensitive resin layer to form a cured product pattern. The photosensitive resin composition in the disposing step may be a photosensitive resin composition of the photosensitive element of the present embodiment. A laminate of the present embodiment is obtained by the method for producing a laminate of the present embodiment, and may be a wiring board (for example, a printed circuit board). The laminate of the present embodiment may be an embodiment having a base material and a cured product pattern (the cured product of the present embodiment) disposed on the base material.

In the disposing step, a photosensitive resin layer composed of the photosensitive resin composition of the present embodiment is disposed on abase material. For example, the photosensitive resin layer may be formed by removing the protective layer from the photosensitive element and then pressure-bonding the photosensitive resin layer of the photosensitive element to the base material while heating the photosensitive resin layer, and may be formed by applying the photosensitive resin composition onto the base material and drying the photosensitive resin composition.

In the exposure step, a region other than a region of the photosensitive resin layer in which a mask is disposed may be exposed and photo-cured by irradiation with an active light ray in a state where the mask is disposed on the photosensitive resin layer, and a part of the photosensitive resin layer may be exposed and photo-cured by irradiation with an active light ray at a desired pattern by a direct writing exposure method such as an LDI exposure method or a DLP exposure method without using a mask. As the light source for the active light ray, an ultraviolet source or a visible light source may be used and examples thereof include a carbon arc lamp, a mercury vapor arc lamp, a high-pressure mercury lamp, a xenon lamp, a gas laser (such as an argon laser), a solid-state laser (such as a YAG laser), and a semiconductor laser.

The development method in the development step may be, for example, wet development or dry development. The wet development can be performed using a developing solution suitable for the photosensitive resin composition, for example, by methods such as a dip method, a paddle method, a spray method, brushing, slapping, scrubbing, and dipping while shaking. The developing solution is appropriately selected in accordance with the configuration of the photosensitive resin composition, and may be an alkaline developing solution or an organic solvent developing solution.

The alkaline developing solution may be aqueous solutions containing bases such as alkali hydroxides such as hydroxides of lithium, sodium, or potassium; alkali carbonates such as carbonates or bicarbonates of lithium, sodium, potassium, or ammonium; alkali metal phosphates such as potassium phosphate and sodium phosphate; alkali metal pyrophosphate such as sodium pyrophosphate and potassium pyrophosphate; borax; sodium metasilicate; tetramethylammonium hydroxide; ethanolamine; ethylenediamine; diethylene triamine; 2-amino-2-hydroxymethyl-1,3-propanediol; 1,3-diamino-2-propanol; and morpholine.

The organic solvent developing solution may contain an organic solvent such as 1,1,1-trichloroethane, N-methylpyrrolidone, N,N-dimethylformamide, cyclohexanone, methyl isobutyl ketone, and γ-butyrolactone.

The base material may have a metal layer, and the photosensitive resin layer may be in contact with the metal layer. In this case, the method for producing a laminate of the present embodiment may include an etching step of etching the metal layer by using the cured product pattern as a mask to remove a part of the metal layer after the development step. In the etching step, a portion where a cured product pattern is not formed in the metal layer (a portion which was covered with the uncured area in the metal layer) can be removed. The metal layer may contain, for example, copper. An etching solution may contain hydrochloric acid, and may contain hydrochloric acid and cupric chloride.

The method for producing a laminate of the present embodiment may include a step of further curing a resist pattern by heating at 60 to 250° C. or exposure at 0.2 to 10 J/cm² after the development step.

The method for producing a laminate of the present embodiment may include a step of removing the cured product pattern after the etching step. The cured product pattern can be removed, for example, using a strong alkaline aqueous solution by performing development such as a dipping method and a spraying method.

### EXAMPLES

Hereinafter, the present disclosure will be further specifically described by means of Examples; however, the present disclosure is not limited to these Examples. Various operations such as exposure and development described below were performed at room temperature (25° C.) under atmospheric pressure as long as conditions were not particularly stated.

### <Synthesis of Binder Polymer>

### (Binder Polymer A1)

A solution a was prepared by mixing 22.0 parts by mass of methacrylic acid, 20.0 parts by mass of styrene, 41.0 parts by mass of methyl methacrylate, 17.0 parts by mass of butyl methacrylate, 0.02 parts by mass of 4-methoxyphenol, and 0.7 parts by mass of azobisisobutyronitrile. Furthermore, a solution b was prepared by mixing 9 parts by mass of propylene glycol monomethyl ether, 7.6 parts by mass of toluene, and 0.14 parts by mass of azobisisobutyronitrile. Further, a solution c was prepared by mixing 4.5 parts by mass of propylene glycol monomethyl ether, 7.6 parts by mass of toluene, and 0.5 parts by mass of azobisisobutyronitrile.

After charging 48 parts by mass of propylene glycol monomethyl ether and 40 parts by mass of toluene in a flask equipped with a stirrer, a reflux condenser, a thermometer, a dropping funnel, and a nitrogen gas inlet tube, stirring was performed at 80° C. for 30 minutes while blowing nitrogen gas into the flask, thereby obtaining a mixed liquid d.

The above-described solution a was added dropwise to the mixed liquid d in the flask over 4 hours, and then stirred at 80° C. for 2 hours. Next, the above-described solution b was added dropwise into the flask and then stirred at 80° C. for 2 hours. Further, while continuing stirring, the temperature of the solution in the flask was increased to 95° C. over 1 hour. Then, the above-described solution c was added dropwise into the flask over 10 minutes and then stirred at 95° C. for 2 hours to perform the reaction, thereby obtaining a reaction solution. After cooling this reaction solution to 50° C., methanol was added to obtain a solution of a binder polymer A1. The non-volatile content (solid content) of the solution of the binder polymer A1 was 47.7% by mass.

### (Binder Polymer A2)

A solution of a binder polymer A2 was obtained by performing the operation in the same manner as in the binder polymer A1, except that a solution a was prepared by mixing 22.0 parts by mass of methacrylic acid, 25.0 parts by mass of styrene, 50.0 parts by mass of methyl methacrylate, 3.0 parts by mass of 2-ethylhexyl acrylate, 0.02 parts by mass of 4-methoxyphenol, and 0.7 parts by mass of azobisisobutyronitrile. The non-volatile content (solid content) of the solution of the binder polymer A2 was 46.3% by mass.

### (Binder Polymer A3)

A solution of a binder polymer A3 was obtained by performing the operation in the same manner as in the binder polymer A1, except that a solution a was prepared by mixing 20.0 parts by mass of methacrylic acid, 15.0 parts by mass of isobornyl methacrylate, 32.0 parts by mass of methyl methacrylate, 15.0 parts by mass of butyl acrylate, 18.0 parts by mass of butyl methacrylate, 0.02 parts by mass of 4-methoxyphenol, and 0.7 parts by mass of azobisisobutyronitrile. The non-volatile content (solid content) of the solution of the binder polymer A3 was 47.7% by mass.

### <Weight Average Molecular Weight (Mw) of Binder Polymer>

The weight average molecular weight of the binder polymer A1 was 3.0×10⁴ and the weight average molecular weight of the binder polymer A2 was 4.5×10⁴. The weight average molecular weight was obtained by measuring with gel permeation chromatography (GPC) under the following conditions and converting using a calibration curve of standard polystyrene. The measurement was performed using a sample obtained by dissolving 120 mg of the solution of the binder polymer in 5 mL of tetrahydrofuran.

### (GPC Conditions)

Pump: Hitachi L-6000 type (manufactured by Hitachi, Ltd., trade name)
Column: Three columns below in total (manufactured by Showa
Denko Materials Techno Service Co., Ltd., trade name, column
specification: 10.7 mmφ×300 mm)
   Gelpack GL-R440
   Gelpack GL-R450
   Gelpack GL-R400M
Eluent: Tetrahydrofuran
Measurement temperature: 40° C.
Injection amount: 200 μL
Pressure: 49 kgf/cm² (4.8 MPa)
Flow rate: 2.05 m/min
Detector: Hitachi L-2490 type RI (manufactured by Hitachi, Ltd., trade name)

### <Preparation of Photosensitive Resin Composition>

A photosensitive resin composition was prepared by mixing each component shown in Table 1, 10 parts by mass of toluene, 5 parts by mass of methanol, and 11 parts by mass of acetone. Table 1 shows the blending amount (parts by mass) of each component, and the blending amount of the binder polymer is the mass (solid content amount) of the non-volatile content. The details of respective components shown in Table 1 are as follows.

### (Photopolymerizable Compound)

### [Monofunctional Photopolymerizable Compound]

NP-8EA: Nonylphenol EO-modified acrylate (an adduct of an average of 8 mol of ethylene oxide, manufactured by Kyoeisha Chemical Co., Ltd.)
FA-MECH: γ-Chloro-β-hydroxypropyl-β′-methacryloyloxyethyl-o-phthalate (manufactured by Showa Denko Materials Co., Ltd.)
HOMPP: Propylene oxide-modified phthalic acid methacrylate (manufactured by Kyoeisha Chemical Co., Ltd., trade name: LIGHT ESTER HOMPP)

### [Bifunctional Photopolymerizable Compound]

FA-321M(70): 2,2-Bis(4-(methacryloxypentaethoxy)phenyl)propane (an adduct of an average of 10 mol of ethylene oxide, EO-modified bisphenol A dimethacrylate, manufactured by Showa Denko Materials Co., Ltd., functionality number: 2, molecular weight: 804)
BPE-900: 2,2-Bis(4-(methacryloxypolyethoxy)phenyl)propane (an adduct of an average of 17 mol of ethylene oxide, EO-modified bisphenol A dimethacrylate, manufactured by SHIN-NAKAMURA CHEMICAL Co., Ltd., functionality number: 2)

### [Tri- or Higher Functional Photopolymerizable Compound]

FA-137M: EO-modified trimethylolpropane trimethacrylate (manufactured by Showa Denko Materials Co., Ltd., functionality number: 3, molecular weight: 1263)
DPEA-12: EO-modified dipentaerythritol hexaacrylate (manufactured by Nippon Kayaku Co., Ltd., functionality number: 6, molecular weight: 1105)

### (Photopolymerization Initiator)

9-PA: 9-Phenylacridine (manufactured by Changzhou Tronly New Electronic Materials Co., Ltd.)
N-PG: N-Phenylglycine (manufactured by Changzhou Tronly New Electronic Materials Co., Ltd.)
EAB: 4,4′-Bis(diethylamino)benzophenone (manufactured by Hodogaya Chemical Co., Ltd.)

### (Other Components)

LCV: Leuco crystal violet (manufactured by Yamada Chemical Co., Ltd.)
TPS: Tribromomethyl phenyl sulfone (manufactured by Changzhou Tronly New Electronic Materials Co., Ltd.)
MKG: Malachite green (manufactured by OSAKA ORGANIC CHEMICAL INDUSTRY LTD.)
LA-7RD: 4-Hydroxy-2,2,6,6-tetramethylpiperidine-N-oxyl (manufactured by Asahi Denka Co., Ltd.)
SF-808H: Mixture of carboxybenzotriazole, 5-amino-1H-tetrazole, and methoxypropanol (manufactured by SANWA KASEI CORP.)
PTSA: p-Toluenesulfonamide (manufactured by JMC)

### <Production of Photosensitive Element>

As a support, a polyethylene terephthalate film (manufactured by Teijin Film Solutions Limited, trade name “G2J”, thickness: 16 μm) was prepared. The above-described photosensitive resin composition was applied onto the support to have an uniform thickness and then sequentially dried with a hot air convection drier set at 70° C. and 110° C. to form a photosensitive resin layer (photosensitive film; average thickness of ten places after drying: 25 μm). A polyethylene film (manufactured by TAMAPOLY CO., LTD., trade name “NF-13”, thickness: 17 μm) as the protective layer was attached onto this photosensitive resin layer, thereby obtaining a photosensitive element having the support, the photosensitive resin layer, and the protective layer in this order.

### <Sensitivity>

A copper-clad laminate plate (manufactured by Showa Denko Materials Co., Ltd., trade name: MCL-E-67) having copper foils (thickness: 18 μm) disposed on both surfaces of a glass epoxy material was pickled, rinsed, and then dried with an air stream to obtain a base material. Next, this base material was heated to 80° C., and then the above-described photosensitive element of Examples was laminated so that the photosensitive resin layer was in contact with the copper surface while the protective layer was peeled off, thereby obtaining a laminate A having the base material (copper-clad laminate plate), the photosensitive resin layer, and the support in this order. The lamination was performed using a heat roll set at 110° C. at a pressure-bonding pressure of 0.4 MPa and at a roll speed of 1.0 m/min.

After a 41-step tablet (manufactured by Showa Denko Materials Co., Ltd., concentration region: 0.00 to 2.00, concentration step: 0.05, tablet size: 20 mm×187 mm, each step size: 3 mm×12 mm) was placed on the support of the above-described laminate A, the photosensitive resin layer was exposed through the support at an exposure dose (irradiation energy dose) for 15 steps remaining on the 41-step tablet after the development by a direct writing exposure machine (manufactured by Orbotech, Nuvogo Fine 8, light source: 375 nm (0%)+405 nm (100%)). The sensitivity (photosensitivity) was evaluated using the exposure dose (unit: mJ/cm²) at this time. The development was performed by peeling off the support and then subjecting an unexposed photosensitive resin layer to spray development (nozzle: full-cone type nozzle, distance between an object to be treated and a nozzle tip: 6 cm) at a pressure of 0.15 MPa using a 1% by mass sodium carbonate aqueous solution set at 30° C. Results are shown in Table 1.

### <Followability>

After etching the copper surface of the copper-clad laminate plate (manufactured by Showa Denko Materials Co., Ltd., trade name: MCL-E-67), a circular hole having a diameter of 200 μm and a depth of 11 μm was formed at eight places, thereby obtaining a base material. Next, this base material was heated to 80° C., and then the above-described photosensitive element was laminated so that the photosensitive resin layer was in contact with the copper surface while the protective layer was peeled off, thereby obtaining a laminate B having the base material (copper-clad laminate plate), the photosensitive resin layer, and the support in this order. The lamination was performed using a heat roll set at 110° C. at a pressure-bonding pressure of 0.3 MPa and at a roll speed of 1.5 m/min.

The circular hole was observed from directly above the above-described laminate B by using an optical microscope (KEYENCE CORPORATION, trade name: VK-8500), and the diameter of air bubbles generated between the circular hole and the photosensitive resin layer in the base material was measured. A case where the diameter was 110 μm or less was evaluated as “A”, a case where the diameter was more than 110 μm and 115 μm or less was evaluated as “B”, and a case where the air bubble diameter was more than 115 μm was evaluated as “C”. Results are shown in Table 1. A smaller diameter of air bubbles indicates excellent followability.

TABLE 1

| | | | | Comparative |
|---|---|---|---|---|
| | | Example | | Example |
| | | 1 | 2 | 1 |
| Binder polymer | A1 | 54 | | |
| | A2 | | 54 | |
| | A3 | | | 60 |
| Photopolymerizable | NP-8EA | 2.0 | | |
| compound | FA-MECH | | 5.0 | |
| | HOMPP | | | 2.0 |
| | FA-321M(70) | 38 | 32 | |
| | BPE-900 | | | 38 |
| | FA-137M | 6.0 | 4.0 | |
| | DPEA-12 | | 5.0 | |
| Photopolymerization | 9-PA | 1.2 | 1.2 | 1.5 |
| initiator | N-PG | 0.03 | 0.03 | 0.5 |
| | EAB | | | 0.1 |
| Other component | LCV | 1.0 | 1.0 | 0.05 |
| | TPS | 0.8 | 0.8 | 0.7 |
| | MKG | 0.03 | 0.03 | 0.5 |
| | LA-7RD | 0.02 | 0.02 | |
| | SF-808H | 0.5 | 0.5 | |
| | PTSA | 2.0 | 2.0 | |
| Evaluation | Sensitivity [mJ/cm²] | 25 | 23 | — |
| | Followability [μm] | A | B | C |

### REFERENCE SIGNS LIST

1: photosensitive element, 2: support, 3: photosensitive resin layer, 4: protective layer.

1. A photosensitive resin composition comprising: (A) a binder polymer; (B) a photopolymerizable compound; and (C) a photopolymerization initiator, wherein
the component (A) includes a binder polymer having a polymerizable monomer having a carboxy group, a styrene compound, an alkyl (meth)acrylate having an alkyl group having 1 to 3 carbon atoms, and an alkyl (meth)acrylate having a linear or branched alkyl group having 4 to 12 carbon atoms as monomer units,
the component (B) includes a monofunctional compound having one ethylenically unsaturated bond, and
the component (C) includes an acridine compound.

2. The photosensitive resin composition according to claim 1, wherein the component (B) includes a nonylphenol EO-modified (meth)acrylate as the monofunctional compound.

3. The photosensitive resin composition according to claim 1, wherein a content of the monofunctional compound is 0.1 to 6 parts by mass with respect to a total of 100 parts by mass of the component (A) and the component (B).

4. The photosensitive resin composition according to claim 1, wherein the component (B) further includes 2,2-bis(4-((meth)acryloxypolyethoxy)phenyl)propane.

5. The photosensitive resin composition according to claim 1, wherein the component (B) further includes 2,2-bis(4-((meth)acryloxypentaethoxy)phenyl)propane.

6. The photosensitive resin composition according to claim 1, wherein the component (B) further includes alkylene oxide-modified trimethylolpropane tri(meth)acrylate.

7. The photosensitive resin composition according to claim 1, wherein a content of the component (B) is 30 to 60 parts by mass with respect to a total of 100 parts by mass of the component (A) and the component (B).

8. The photosensitive resin composition according to claim 1, wherein a content of the monomer unit of the styrene compound is more than 20% by mass on the basis of a total amount of monomer units constituting the component (A).

9. The photosensitive resin composition according to claim 1, wherein a weight average molecular weight of the component (A) is 3.0×10⁴ to 5.0×10⁴.

10. The photosensitive resin composition according to claim 1, wherein the component (C) further includes a N-phenylglycine compound.

11. The photosensitive resin composition according to claim 1, further comprising p-toluenesulfonamide.

12. The photosensitive resin composition according to claim 1, further comprising a polymerization inhibitor.

13. The photosensitive resin composition according to claim 1, which is in a film form.

14. A photosensitive element comprising: a support; and a photosensitive resin layer disposed on the support, wherein
the photosensitive resin layer is a layer of the photosensitive resin composition according to claim 1.

15. A method for producing a laminate, the method comprising:
a step of disposing a layer of the photosensitive resin composition on a base material by using the photosensitive resin composition according to claim 1;
a step of photo-curing a part of the layer of the photosensitive resin composition; and
a step of removing at least a part of an uncured area of the layer of the photosensitive resin composition to form a cured product pattern.

16. A method for producing a laminate, the method comprising:
a step of disposing a layer of the photosensitive resin composition on a base material by using the photosensitive element according to claim 14;
a step of photo-curing a part of the layer of the photosensitive resin composition; and
a step of removing at least a part of an uncured area of the layer of the photosensitive resin composition to form a cured product pattern.

17. The photosensitive resin composition according to claim 5, wherein a content of the monomer unit of the polymerizable monomer having a carboxy group is 1 to 28% by mass on the basis of a total amount of monomer units constituting the component (A).

18. The photosensitive resin composition according to claim 5, wherein a content of the monomer unit of the alkyl (meth)acrylate having an alkyl group having 1 to 3 carbon atoms is 40 to 70% by mass on the basis of a total amount of monomer units constituting the component (A).

19. The photosensitive resin composition according to claim 5, wherein a content of the monomer unit of the alkyl (meth)acrylate having a linear or branched alkyl group having 4 to 12 carbon atoms is 12 to 30% by mass on the basis of a total amount of monomer units constituting the component (A).

20. The photosensitive resin composition according to claim 5, wherein a content of the monofunctional compound is more than 0 parts by mass and 15 parts by mass or less with respect to a total of 100 parts by mass of the component (A) and the component (B).
